(19) United States
(12) Patent Application Publication
(10) Pub. No.: US 2019/0259798 A1
(43) Pub. Date: Aug. 22, 2019

(54) ACTIVE MATRIX SUBSTRATE, X-RAY IMAGING PANEL INCLUDING SAME, AND PRODUCING METHOD THEREOF

(71) Applicant: SHARP KABUSHIKI KAISHA, Sakai City (JP)

(72) Inventor: KATSUNORI MISAKI, Yonago-shi (JP)

(21) Appl. No.: 16/277,966

(22) Filed: Feb. 15, 2019

(30) Foreign Application Priority Data
Feb. 16, 2018 (JP) 2018-026463

(51) Int. Cl. H01L 27/146; H01L 21/02; H01L 31/20; H01L 31/0376; H01L 31/105; G01T 1/20

(52) U.S. Cl. CPC H01L 27/14636; H01L 27/1462; H01L 27/14663; H01L 27/14612; H01L 27/14685; G01T 1/2018; H01L 27/14692; H01L 31/202; H01L 27/14689; H01L 31/03762; H01L 31/1055; H01L 21/02057

(57) ABSTRACT

Provided is a technique with which detection defects due to a higher resistance of bias lines can be suppressed. An active matrix substrate 1 has a plurality of detection circuitry arranged in matrix. Each of the detection circuitry includes a photoelectric conversion layer 15; a pair of a first electrode 14a and a second electrode 14b between which the photoelectric conversion layer 15 is interposed; an insulating film 106 covering a side end portion of the photoelectric conversion layer 15; a bias line 16 that is provided on the insulating film 106, and applies a bias voltage to the second electrode 14b; and a protection film 17 that is provided on the insulating film 106, covers a surface of the bias line 16, and contains a conductive material having resistance against acid. At least at a part of the second electrode 14b covers the protection film 17.

### TECHNICAL FIELD

The present invention relates to an active matrix substrate, an X-ray imaging panel including the same, and a method for producing the same.

### BACKGROUND ART

Conventionally, an X-ray imaging device is known that includes thin film transistors (also referred to as “TFTs”) in a plurality of areas arranged in matrix (hereinafter referred to as pixel portions), and picks up an image of irradiated X-rays with a plurality of pixel portions. In such an X-ray imaging device, for example, p-intrinsic-n (PIN) photodiodes are used as photoelectric conversion elements that convert irradiated X-rays into charges. The converted charges are read out by causing the TFTs of the respective pixels to operate. With the charges being read out in this way, an X-ray image is obtained.

Patent Document 1 discloses such an X-ray imaging device. More specifically, in the configuration disclosed in Patent Document 1, of a pair of electrodes between which the photodiode is interposed, i.e., a first electrode and a second electrode, the first electrode is connected with a TFT, and the second electrode is connected with a bias line. The bias line is formed over an entire light incident surface of each pixel portion.

### PRIOR ART DOCUMENT

### Patent Document

Patent Document 1: JP-A-2011-159781

### SUMMARY OF THE INVENTION

Incidentally, a native oxide adhering to the surface of the PIN photodiode is removed by using hydrofluoric acid in some cases. For example, in a configuration in which a bias line is provided outside the PIN photodiode and the bias line is connected with an upper electrode, if the bias line has been already formed before the cleaning with use of hydrofluoric acid the bias line is exposed to hydrofluoric acid. In a case where a metal material such as aluminum (Al) having a low resistance against hydrofluoric acid is contained in the bias line, sides of the bias line is etched by the cleaning treatment, whereby the bias line has a smaller line width. As a result, the bias line has a higher resistance, resulting in that X-ray detection defects occur.

It is an object of the present invention to provide a technique of suppressing detection defects due to a higher resistance of bias lines.

An active matrix substrate of the present invention, with which the above-described problem is solved, is an active matrix substrate having a plurality of detection circuitry arranged in matrix, each of the detection circuitry includes: a photoelectric conversion layer; a pair of a first electrode and a second electrode between which the photoelectric conversion layer is interposed; an insulating film that covers a side surface of the photoelectric conversion layer; a bias line that is provided on the insulating film and applies a bias voltage to the second electrode; and a protection film that is provided on the insulating film, covers a surface of the bias line, and contains a conductive material having resistance against an acid, wherein at least a part of the second electrode covers the protection film.

According to the above configuration, detection defects due to a higher resistance of bias lines can be decreased.

### BRIEF DESCRIPTION OF DRAWINGS

FIG. 1 schematically illustrates an X-ray imaging device in Embodiment 1.

FIG. 2 schematically illustrates a schematic configuration of the active matrix substrate illustrated in FIG. 1.

FIG. 3 is an enlarged plan view showing one pixel portion of the active matrix substrate illustrated in FIG. 2.

FIG. 4 is a cross-sectional view of the pixel shown in FIG. 3, taken along line A-A.

FIG. 5 is an enlarged view showing a portion in the broken-line frame in FIG. 4.

FIG. 6A is a cross-sectional view showing a step in a process for producing the active matrix substrate shown in FIG. 4, the step being a step of forming a first insulating film, in a state in which a gate insulating film and a TFT are formed on a substrate.

FIG. 6B is a cross-sectional view showing a step of patterning the first insulating film shown in FIG. 6A so as to form an opening in the first insulating film.

FIG. 6C is a cross-sectional view showing a step of forming the second insulating film shown in FIG. 4.

FIG. 6D is a cross-sectional view showing a step of patterning the second insulating film shown in FIG. 6C so as to form an opening in the second insulating film.

FIG. 6E is a cross-sectional view showing a step of forming a metal film that will become the lower electrode shown in FIG. 4.

FIG. 6F is a cross-sectional view showing a step of patterning the metal film illustrated in FIG. 6E so as to form the lower electrode.

FIG. 6G is a cross-sectional view showing a step of forming an n-type amorphous semiconductor layer, an intrinsic amorphous semiconductor layer, and a p-type amorphous semiconductor layer as the photoelectric conversion layer shown in FIG. 4.

FIG. 6H is a cross-sectional view showing a step of patterning the n-type amorphous semiconductor layer, the intrinsic amorphous semiconductor layer, and the p-type amorphous semiconductor layer shown in FIG. 6G so as to form the photoelectric conversion layer.

FIG. 6I is a cross-sectional view showing a step of forming the third insulating film shown in FIG. 4.

FIG. 6J is a cross-sectional view showing a step of patterning the third insulating film shown in FIG. 6I so as to form an opening in the third insulating film.

FIG. 6K is a cross-sectional view showing a step of forming the fourth insulating film shown in FIG. 4.

FIG. 6L is a cross-sectional view showing a step of patterning the fourth insulating film shown in FIG. 6K so as to form an opening in the fourth insulating film.

FIG. 6M is a cross-sectional view showing a step of forming a metal film that will become the bias line shown in FIG. 4.

FIG. 6N is a cross-sectional view showing a step of patterning the metal film shown in FIG. 6M so as to form the bias line.

FIG. 6O is a cross-sectional view showing a step of forming a metal film that will become the protection film shown in FIG. 4.

FIG. 6P is a cross-sectional view showing a step of patterning the metal film shown in FIG. 6O so as to form the protection film, and washing the surface of the photoelectric conversion layer with hydrofluoric acid.

FIG. 6Q is a cross-sectional view showing a step of forming a transparent conductive film that will become the upper electrode shown in FIG. 4.

FIG. 6R is a cross-sectional view showing a step of patterning the transparent conductive film shown in FIG. 6Q so as to form the upper electrode.

FIG. 6S is a cross-sectional view showing a step of forming the fifth insulating film shown in FIG. 4.

FIG. 6T is a cross-sectional view showing a step of forming the sixth insulating film shown in FIG. 4.

FIG. 7A is a cross-sectional view showing a step in a process in Embodiment 2 for producing the active matrix substrate shown in FIG. 4, the step being a step of forming a fourth insulating film on the third insulating film.

FIG. 7B is a cross-sectional view showing a step of forming an opening in the fourth insulating film shown in FIG. 7A.

FIG. 7C is a cross-sectional view showing a step of forming an opening in the third insulating film shown in FIG. 7B.

FIG. 8A is a cross-sectional view showing a step in a process in Embodiment 3 for producing the active matrix substrate shown in FIG. 4, the step being a step of forming a metal film that will become a bias line.

FIG. 8B is a cross-sectional view showing a step of forming a bias line by patterning the metal film shown in FIG. 8A.

FIG. 8C is a cross-sectional view showing a step of forming a metal film that will become a protection film so as to cover the bias line shown in FIG. 8B.

FIG. 8D is a cross-sectional view showing a step of patterning the metal film shown in FIG. 8C so as to form the protection film

FIG. 8E is a cross-sectional view showing a step of forming an opening in the third insulating film shown in FIG. 8D.

FIG. 9A is a cross-sectional view showing a step in a process in Embodiment 4 for producing the active matrix substrate shown in FIG. 4, the step being a step of forming a metal film that will become a bias line on the fourth insulating film.

FIG. 9B is a cross-sectional view showing a step of patterning the metal film shown in FIG. 9A so as to form the bias line.

FIG. 9C is a cross-sectional view showing a step of forming a metal film that will become a protection film so as to cover the bias line shown in FIG. 9B.

FIG. 9D is a cross-sectional view showing a step of patterning the metal film shown in FIG. 9C so as to form the protection film.

FIG. 9E is a cross-sectional view showing a step of forming an opening in the fourth insulating film shown in FIG. 9D.

FIG. 9F is a cross-sectional view showing a step of forming an opening in the third insulating film shown in FIG. 9E.

### MODE FOR CARRYING OUT THE INVENTION

An active matrix substrate according to one embodiment of the present invention is an active matrix substrate having a plurality of detection circuitry arranged in matrix, each of the detection circuitry includes: a photoelectric conversion layer; a pair of a first electrode and a second electrode between which the photoelectric conversion layer is interposed; an insulating film that covers a side surface of the photoelectric conversion layer; a bias line that is provided on the insulating film and applies a bias voltage to the second electrode; and a protection film that is provided on the insulating film, covers a surface of the bias line, and contains a conductive material having resistance against an acid, wherein at least a part of the second electrode covers the protection film (the first configuration).

According to the first configuration, on the insulating film covering the side surface of the photoelectric conversion layer, the bias line as well as the protection film covering the bias line are provided, and the second electrode covers the protection film. The protection film contains a conductive material that has resistance against acid. Since the bias line is covered with the protection film, even if etching or cleaning with use of acid is carried out after the protection film is formed, the bias line is not exposed to the acid, and the bias line therefore is not dissolved by the acid. The bias line is therefore formed so as to keep a fixed width, whereby detection defects due to a higher resistance of the bias lines can be decreased.

The first configuration may be further characterized in that the bias line is made of a metal material containing any one of aluminum, copper, and silver (the second configuration).

According to the second configuration, the bias line is made of a metal material having a relatively low resistance, which makes it possible to improve the detection performance.

The first configuration may be further characterized in that the insulating film has an opening on the photoelectric conversion layer, and the second electrode is in contact with the photoelectric conversion layer in the opening (the third configuration).

According to the third configuration, the second electrode and the photoelectric conversion layer are in contact with each other through the opening on the photoelectric conversion layer, and the bias line and the protection film are not arranged on the photoelectric conversion layer. The transmittance therefore does not decrease, and the detection accuracy can be improved, as compared with a case where the bias line and the protection film are arranged on the photoelectric conversion layer.

Any one of the first to third configurations may be further characterized in that the acid contains hydrofluoric acid (the fourth configuration).

According to the fourth configuration, the protection film has resistance against hydrofluoric acid, which results in that even if the protection film is exposed to hydrofluoric acid, the bias line therefore is not dissolved by acid, and therefore can keep a fixed width.

An X-ray imaging panel according to one embodiment of the present invention includes an active matrix substrate according to any one of the first to fourth configurations, and a scintillator that convers irradiated X-rays into scintillation light (the fifth configuration).

With the fifth configuration, the bias line can be formed so as to keep a fixed width, whereby scintillation light detection defects due to a higher resistance of the bias lines can be suppressed.

A method for producing an active matrix substrate according to one embodiment of the present invention is a method for producing an active matrix substrate having a plurality of detection circuitry arranged in matrix, the producing method comprising the steps of, in each of areas where the detection circuitry on the substrate are provided, respectively: forming a first electrode; forming a photoelectric conversion layer on the first electrode; forming an insulating film that has an opening on the photoelectric conversion layer and covers a side surface of the photoelectric conversion layer; forming a bias line on an outer side with respect to the photoelectric conversion layer, on the insulating film; forming a protection film covering a surface of the bias line, on the insulating film; and forming a second electrode that is in contact with the photoelectric conversion layer in the opening, and the overlaps the with the protection film, wherein the protection film contains a conductive material having resistance against acid (the first producing method).

According to the first producing method, on an outer side with respect to the photoelectric conversion layer, the bias line, and the protection film covering the bias line, are formed on the insulating film covering the side surface of the photoelectric conversion layer. The second electrode overlaps with the protection film, and is in contact with the photoelectric conversion layer in the opening of the insulating film. The protection film contains a conductive material having resistance against hydrofluoric acid. Since the surface of the bias line is covered with the protection film, even if etching with use of acid is carried out after the protection film is formed, the bias line is not exposed to the acid, and the width of the bias line therefore can be kept fixed. As a result, detection defects due to a higher resistance of the bias lines can be decreased.

The first producing method may be further characterized in that the acid contains hydrofluoric acid (the second producing method).

According to the second producing method, the protection film has resistance hydrofluoric acid. Even if the protection film is exposed to hydrofluoric acid after being formed, the bias line therefor is not dissolved, and can keep a fixed width.

The first or second producing method may be further characterized in further including the step of cleaning a surface of the photoelectric conversion layer with hydrofluoric acid, the cleaning step being carried out after the step of forming the protection film, and before the step of forming the second electrode (the third producing method).

According to the third producing method, the surface of the photoelectric conversion layer is cleaned with use of hydrofluoric acid, whereby a native oxide or the like adhering to the surface of the photoelectric conversion layer can be removed. Besides, since the bias line is covered with the protection film, the bias line is not affected by the cleaning treatment with use of hydrofluoric acid.

Any one of the first to third producing methods may be further characterized in that, in the step of forming the insulating film, the insulating film is formed so as to cover the photoelectric conversion layer, and after the steps of forming the bias line and forming the protection film are carried out, the insulating film on the photoelectric conversion layer is etched with use of hydrofluoric acid so that the opening is formed at a position overlapping the photoelectric conversion layer in a planar view (the fourth producing method).

According to the fourth producing method, when the insulating film on the photoelectric conversion layer is etched with use of acid, the bias line is covered with the protection film, whereby the bias line is not exposed to hydrofluoric acid. This therefore allows the bias line to keep a fixed width.

The following description describes embodiments of the present invention in detail, while referring to the drawings. Identical or equivalent parts in the drawings are denoted by the same reference numerals, and the descriptions of the same are not repeated.

### Embodiment 1

### (Configuration)

FIG. 1 schematically illustrates an X-ray imaging device in the present embodiment. The X-ray imaging device 100 includes an active matrix substrate 1 and a control unit 2. The control unit 2 includes a gate control unit 2A and a signal reading unit 2B. X-rays are projected from the X-ray source 3 to an object S, and X-rays transmitted through the object S are converted into fluorescence (hereinafter referred to as scintillation light) by a scintillator 4 provided above the active matrix substrate 1. The X-ray imaging device 100 picks up the scintillation light with the active matrix substrate 1 and the control unit 2, thereby acquiring an X-ray image.

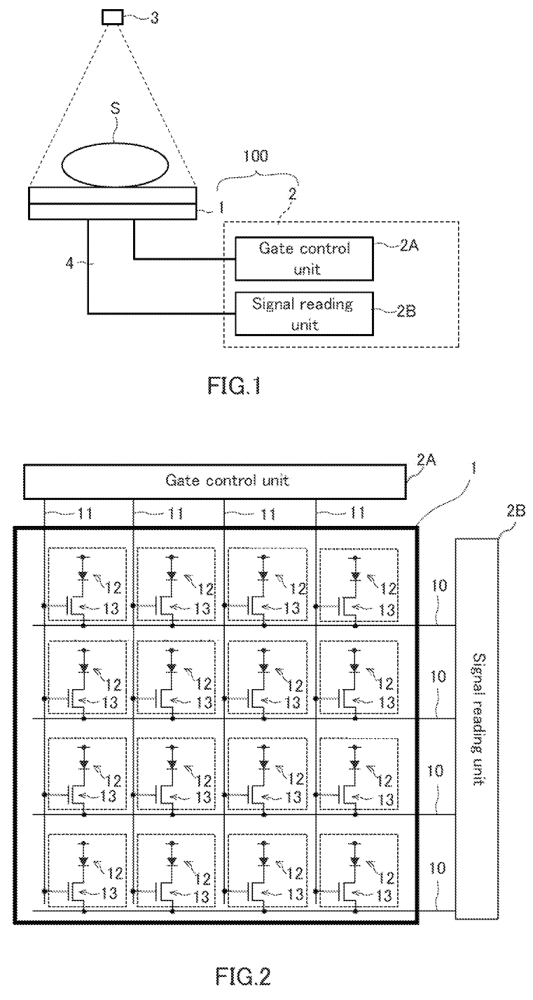

FIG. 2 is a schematic diagram showing a schematic configuration of the active matrix substrate 1. As shown in FIG. 2, a plurality of source lines 10, and a plurality of gate lines 11 intersecting with the source lines 10 are formed in the active matrix substrate 1. The gate lines 11 are connected with the gate control unit 2A, and the source lines 10 are connected with the signal reading unit 2B.

The active matrix substrate 1 includes TFTs 13 connected to the source lines 10 and the gate lines 11, at positions at which the source lines 10 and the gate lines 11 intersect. Further, photodiodes 12 are provided in areas surrounded by the source lines 10 and the gate lines 11 (hereinafter referred to as pixels). In each pixel, scintillation light obtained by converting X-rays transmitted through the object S is converted by the photodiode 12 into charges according to the amount of the light. In other words, the pixels function as detection units that detect scintillation light.

The gate lines 11 in the active matrix substrate 1 are sequentially switched by the gate control unit 2A into a selected state, and the TFT 13 connected to the gate line 11 in the selected state is turned ON. When the TFT 13 is turned ON, a signal according to the charges obtained by the conversion by the photodiode 12 is output through the source line 10 to the signal reading unit 2B.

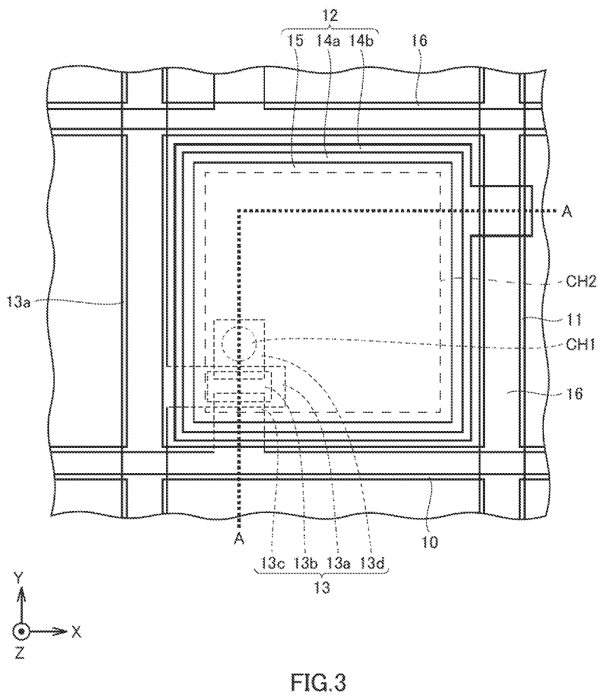

FIG. 3 is an enlarged plan view of one pixel portion of the active matrix substrate 1 illustrated in FIG. 2. As illustrated in FIG. 3, in the pixel surrounded by the gate lines 11 and the source lines 10, the photodiode 12 and the TFT 13 are arranged.

The photodiode 12 includes a lower electrode 14a and an upper electrode 14b as a pair of a first electrode and a second electrode, and a photoelectric conversion layer 15.

The upper electrode 14b is provided on the photoelectric conversion layer 15, that is, on a side that is irradiated with X-rays from the X-ray source 3 (see FIG. 1).

The TFT 13 includes a gate electrode 13a integrated with the gate line 11, a semiconductor active layer 13b, a source electrode 13c integrated with the source line 10, and a drain electrode 13d.

Further, the bias line 16 is arranged so as to overlap with the gate line 11 and the source line 10 when viewed in a plan view. The bias line 16 supplies a bias voltage to the photodiode 12.

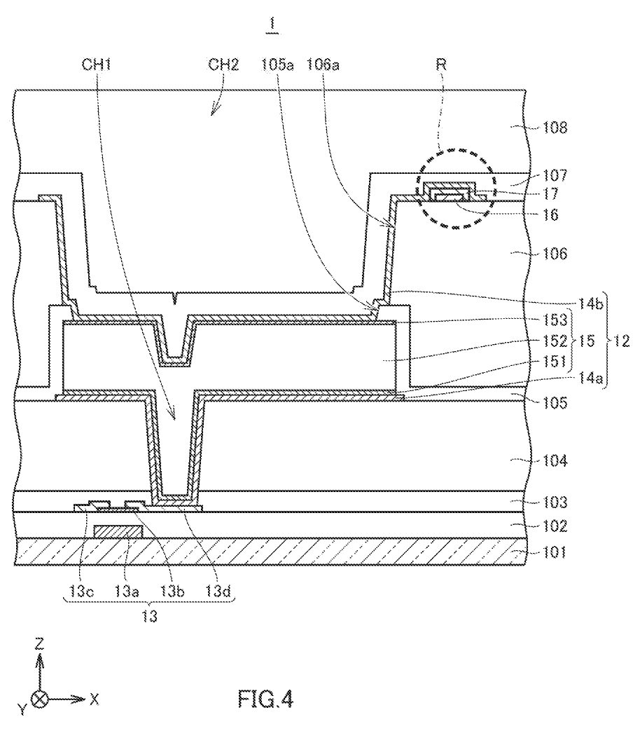

Here, FIG. 4 shows a cross-sectional view of the pixel shown in FIG. 3 taken along line A-A. As shown in FIG. 4, each element in the pixel is arranged on the substrate 101. The substrate 101 is a substrate having insulating properties, and is formed with, for example, a glass substrate.

On the substrate 101, the gate electrode 13a integrated with the gate line 11 (see FIG. 3), and a gate insulating film 102.

The gate electrode 13a and the gate line 11 are made of, for example, a metal such as aluminum (Al), tungsten (W), molybdenum (Mo), molybdenum-niobium (MoNb), tantalum (Ta), chromium (Cr), titanium (Ti), or copper (Cu), an alloy of any of these metals, or a metal nitride of these metals. In this example, the gate electrode 13a and the gate line 11 may have laminate structures each of which is obtained by laminating a metal film made of molybdenum-niobium (MoNb) as an upper layer, and a metal film made of aluminum (Al) as a lower layer. In this case, the metal film made of molybdenum-niobium (MoNb) preferably has a thickness of about 100 nm, and the metal film made of aluminum (Al) preferably has a thickness of about 300 nm. The materials and the thicknesses of the gate electrode 13a and the gate line 11, however, are not limited to these.

The gate insulating film 102 covers the gate electrode 13a. For forming the gate insulating film 102, for example, the following can be used: silicon oxide (SiOₓ); silicon nitride (SiNₓ); silicon oxide nitride (SiOₓN_{y}) (x>y); or silicon nitride oxide (SiNₓO_{y}) (x>y).

In this example, the gate insulating film 102 may be formed with a laminate film obtained by laminating silicon oxide (SiOₓ) and silicon nitride (SiNₓ) in the order. In this case, regarding the thicknesses of these films, it is preferable that the film of silicon oxide (SiOₓ) has a thickness of about 50 nm, and the film of silicon nitride (SiNₓ) has a thickness of about 400 nm. The material and the thickness of the gate insulating film 102, however, are not limited to these.

The semiconductor active layer 13b, as well as the source electrode 13c and the drain electrode 13d connected with the semiconductor active layer 13b are formed on the gate electrode 13a with the gate insulating film 102 being interposed therebetween.

The semiconductor active layer 13b is formed in contact with the gate insulating film 102. The semiconductor active layer 13b is made of an oxide semiconductor. For forming the oxide semiconductor, for example, the following material may be used: InGaO₃(ZnO)₅; magnesium zinc oxide (MgₓZn₁₋ₓO); cadmium zinc oxide (CdₓZn₁₋ₓO); cadmium oxide (CdO); or an amorphous oxide semiconductor containing indium (In), gallium (Ga), and zinc (Zn) at a predetermined ratio.

In this example, it is preferable that the semiconductor active layer 13b is made of, for example, an amorphous oxide semiconductor containing indium (In), gallium (Ga), and zinc (Zn) at a predetermined ratio, and has a thickness of about 70 nm. The material and the thickness of the semiconductor active layer 13b, however, are not limited to these.

The source electrode 13c and the drain electrode 13d, on the gate insulating film 102, are arranged so as to be in contact with parts of the semiconductor active layer 13b. The drain electrode 13d is connected with the lower electrode 14a through the contact hole CH1.

The source electrode 13c and the drain electrode 13d are formed in the same layer, and are made of, for example, a metal such as aluminum (Al), tungsten (W), molybdenum (Mo), tantalum (Ta), chromium (Cr), titanium (Ti), or copper (Cu), or alternatively, an alloy of any of these, of a metal nitride of any of these. Further, as the material for the source electrode 13c and the drain electrode 13d, the following material may be used: a material having translucency such as indium tin oxide (ITO), indium zinc oxide (IZO), indium tin oxide (ITSO) containing silicon oxide, indium oxide (In₂O₃), tin oxide (SnO₂), zinc oxide (ZnO), or titanium nitride; or a material obtained by appropriately combining any of these.

In this example, the source electrode 13c and the drain electrode 13d has a laminate structure obtained by laminating a plurality of metal films. More specifically, the source electrode 13c and the drain electrode 13d are formed with a metal film made of molybdenum-niobium (MoNb), a metal film made of aluminum (Al), and a metal film made of molybdenum-niobium (MoNb) which are laminated in this order. In this case, regarding the thicknesses of the films, preferably, the metal film in the lower layer, which is made of molybdenum-niobium (MoNb), has a thickness of about 50 nm, the metal film made of aluminum (Al) has a thickness of about 500 nm, and the metal film in the upper layer, which is made of molybdenum-niobium (MoNb), has a thickness of about 100 nm. The materials and the thicknesses of the source electrode 13c and the drain electrode 13d, however, are not limited to these.

A first insulating film 103 is provided so as to cover the source electrode 13c and the drain electrode 13d. In this example, the first insulating film 103 has a laminate structure obtained by laminating silicon nitride (SiN) and silicon oxide (SiO₂) in this order. In this case, it is preferable that, for example, the silicon nitride (SiN) film has a thickness of about 330 nm, and the silicon oxide (SiO₂) film has a thickness of about 200 nm. The material and the thickness of the first insulating film 103, however, are not limited to these. Further, the first insulating film 103 may have a single layer structure made of silicon oxide (SiO₂) or silicon nitride (SiN).

On the first insulating film 103, a second insulating film 104 is formed. On the drain electrode 13d, the contact hole CH1 is formed. The contact hole CH1 passes through the second insulating film 104 and the first insulating film 103. In this example, the second insulating film 104 is formed with an organic transparent resin such as acrylic resin or siloxane-based resin. In this case, the second insulating film 104 preferably has a thickness of about 2.5 μm. The thickness of the second insulating film 104, however, is not limited to this.

On the second insulating film 104, the lower electrode 14a is formed. The lower electrode 14a is connected with the drain electrode 13d through the contact hole CH1. In this example, the lower electrode 14a is formed with, for example, a metal film containing molybdenum-niobium (MoNb). In this case, the lower electrode 14a preferably has a thickness of about 200 nm. The material and the thickness of the lower electrode 14a, however, are not limited to these.

On the lower electrode 14a, the photoelectric conversion layer 15 is formed. The photoelectric conversion layer 15 is composed of the n-type amorphous semiconductor layer 151, the intrinsic amorphous semiconductor layer 152, and the p-type amorphous semiconductor layer 153, which are laminated in the order. In this example, the photoelectric conversion layer 15 has an X-axis-direction length shorter than the X-axis-direction length of the lower electrode 14a.

The n-type amorphous semiconductor layer 151 is made of amorphous silicon doped with an n-type impurity (for example, phosphorus). In this example, the n-type amorphous semiconductor layer 151 preferably has a thickness of about 30 nm. The dopant material and the thickness of the n-type amorphous semiconductor layer 151, however, are not limited to these.

The intrinsic amorphous semiconductor layer 152 is made of intrinsic amorphous silicon. The intrinsic amorphous semiconductor layer 152 is formed in contact with the n-type amorphous semiconductor layer 151. In this example, the intrinsic amorphous semiconductor layer preferably has a thickness of about 1000 nm, but the thickness thereof is not limited to this.

The p-type amorphous semiconductor layer 153 is made of amorphous silicon doped with a p-type impurity (for example, boron). The p-type amorphous semiconductor layer 153 is formed in contact with the intrinsic amorphous semiconductor layer 152. In this example, the p-type amorphous semiconductor layer 153 preferably has a thickness of about 5 nm. The dopant material and the thickness of the p-type amorphous semiconductor layer 153, however, are not limited to these.

On the second insulating film 104, the third insulating film 105 is provided. The third insulating film 105 covers the side surfaces of the lower electrode 14a and the photoelectric conversion layer 15, and has an opening 105a on the photoelectric conversion layer 15. In this example, the third insulating film 105 is an inorganic insulating film made of, for example, silicon nitride (SiN). The third insulating film 105 preferably has a thickness of about 300 nm. The material and the thickness of the third insulating film 105 are not limited to these.

On the third insulating film 105, the fourth insulating film 106 is provided. The fourth insulating film 106 has an opening 106a on the opening 105a of the third insulating film 105, the opening 106a having a greater opening width than the width of the opening 105a. The fourth insulating film 106 is provided so as to overlap with the side surfaces of the photoelectric conversion layer 15 when viewed in a plan view. In other words, the fourth insulating film 106 covers the side surfaces of the photoelectric conversion layer 15 with the third insulating film 105 being interposed between the fourth insulating film 106 and the photoelectric conversion layer 15. The openings 105a and 106a compose a contact hole CH2. In this example, the fourth insulating film 106 is an organic insulating film made of, for example, acrylic resin or siloxane-based resin. The fourth insulating film 106 preferably has a thickness of about 2.5 μm. The material and the thickness of the fourth insulating film 106, however, are not limited to these.

The bias line 16 is provided on the fourth insulating film 106, on an outer side with respect to the photoelectric conversion layer 15. The bias line 16 is formed with a metal film.

Further, on the fourth insulating film 106, a protection film 17 that covers the surface of the bias line 16 is provided. The protection film 17 is formed with a metal film.

The upper electrode 14b is in contact with the photoelectric conversion layer 15 in the contact hole CH2, and covers the protection film 17. The upper electrode 14b is formed with a transparent conductive film, and in this example, it is made of indium tin oxide (ITO). The upper electrode 14b preferably has a thickness of about 70 nm. The material and the thickness of the upper electrode 14b, however, are not limited to these.

The bias line 16 is connected with the control unit 2 (see FIG. 1), and applies a bias voltage input from the control unit 2 to the upper electrode 14b through the protection film 17.

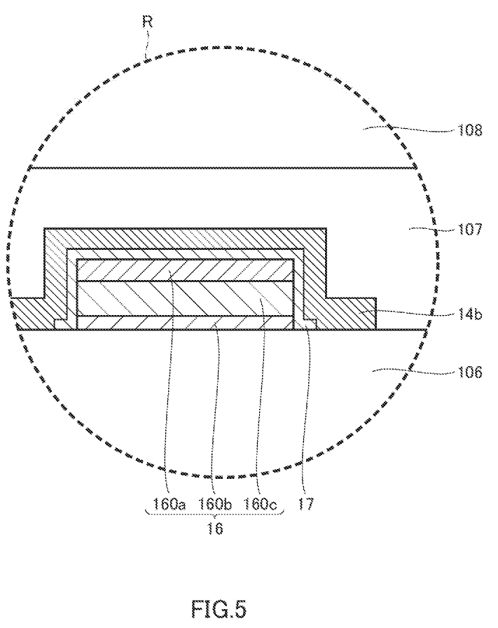

Here, the following description specifically describes the structure of the bias line 16 in the present embodiment. FIG. 5 is an enlarged view illustrating the broken line frame R shown in FIG. 4.

As shown in FIG. 5, the bias line 16 has a laminate structure obtained by laminating three metal films 160a to 160c. In this example, the metal films 160a and 160b, which are the uppermost layer and the lowermost layer, respectively, are made of molybdenum-niobium (MoNb), and the metal film 160c, which is the intermediate layer, is made of aluminum (Al). The metal films 160a to 160c preferably have thicknesses of about 100 nm, 300 nm, and 50 nm, respectively. The materials and thicknesses of the films of the bias line 16 however, are not limited to these. The bias line 16 preferably contain a metal material having a relatively low resistance. The metal material having a low resistance may contain a metal material such as copper (Cu), or silver (Ag), in addition to aluminum (Al).

In this example, the protection film 17 is made of molybdenum-niobium (MoNb), and preferably has a thickness of about 300 nm. Though the material and the thickness of the protection film 17 are not limited to these, it is preferable that the protection film 17 is made of a material that has conductivity, and has resistance against acid such as hydrofluoric acid or solution of ammonium fluoride. More specifically, other than molybdenum-niobium (MoNb), for example, any one of molybdenum (Mo), tungsten (W), tantalum (Ta), nickel (Ni), or lead (Pb), or alternatively, an alloy of any of these, or further alternatively, any one of ITO, IZO, and IGZO, may be used.

Referring back to FIG. 4, a fifth insulating film 107 is provided so as to cover the upper electrode 14b and the fourth insulating film 106. The fifth insulating film 107 is an inorganic insulating film, and in this example, it is made of silicon nitride (SiN). In this case, the fifth insulating film 107 preferably has a thickness of about 200 nm. The material and the thickness of the fifth insulating film 107, however, are not limited to these.

A sixth insulating film 108 is provided so as to cover the fifth insulating film 107. The sixth insulating film 108 is an organic insulating film, and in this example, it is made of an organic transparent resin such as acrylic resin or siloxane-based resin. The sixth insulating film 108 preferably has a thickness of about 2.0 μm. The material and the thickness of the sixth insulating film 108, however, are not limited to these.

### (Method for Producing Active Matrix Substrate 1)

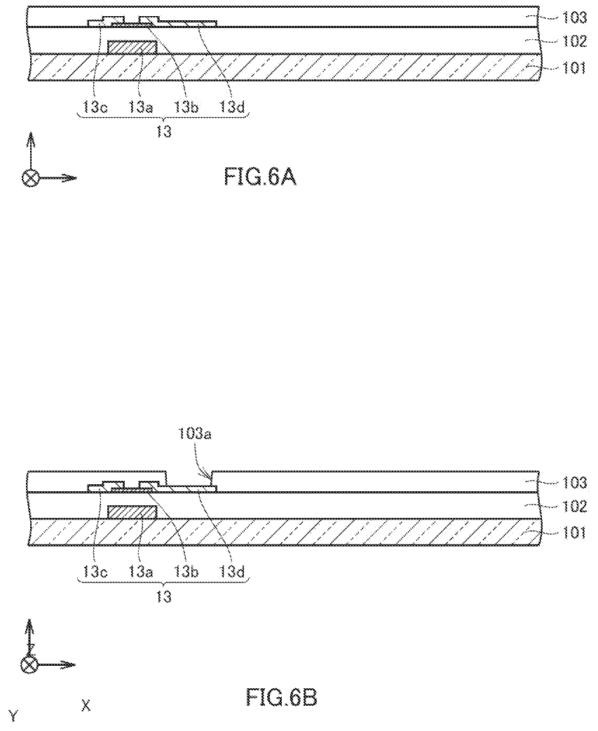

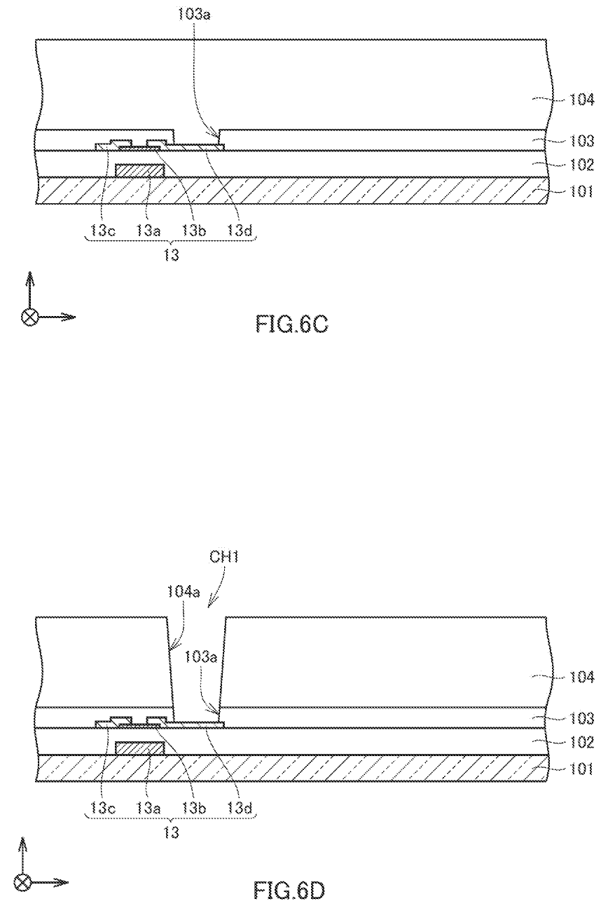

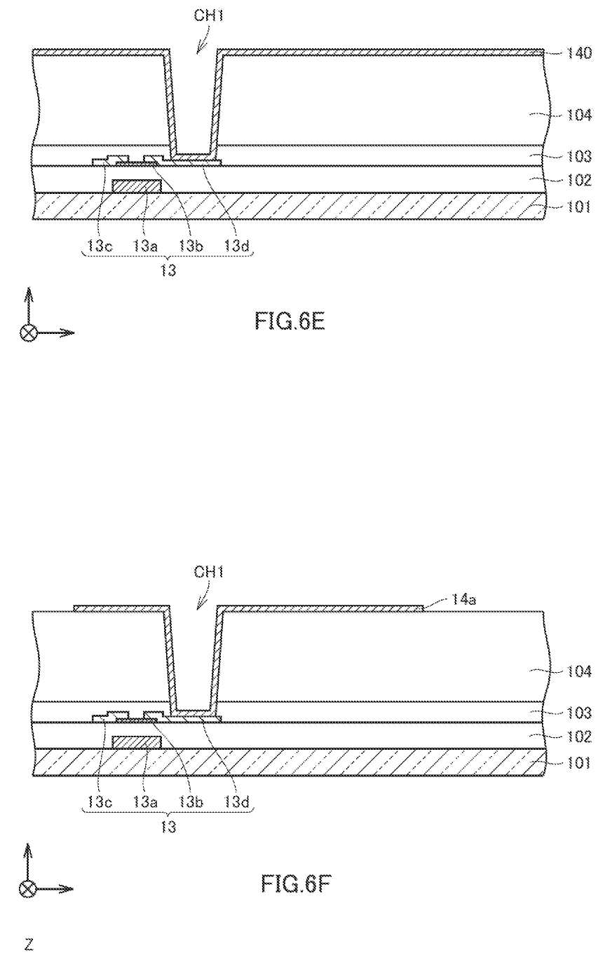

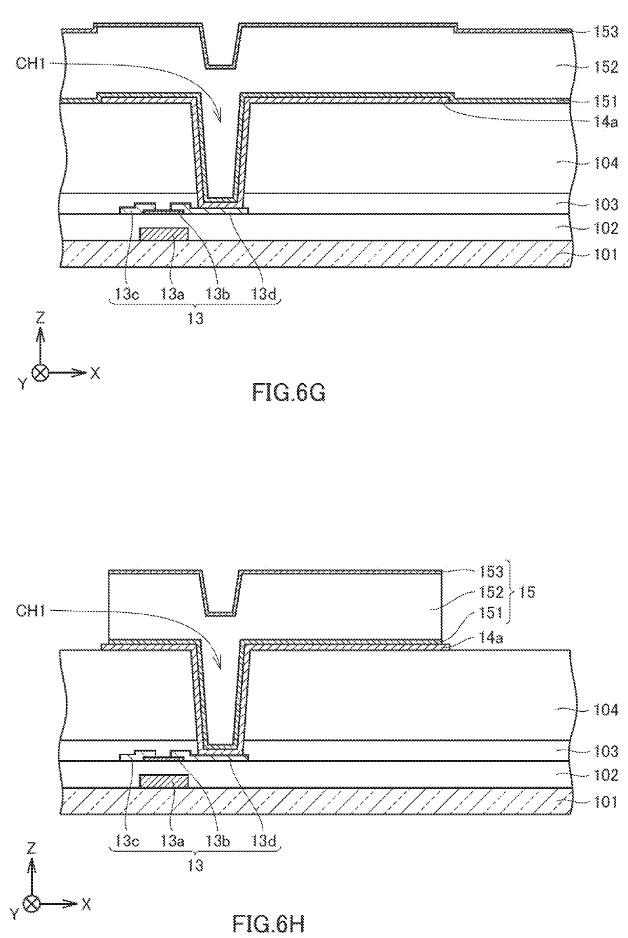

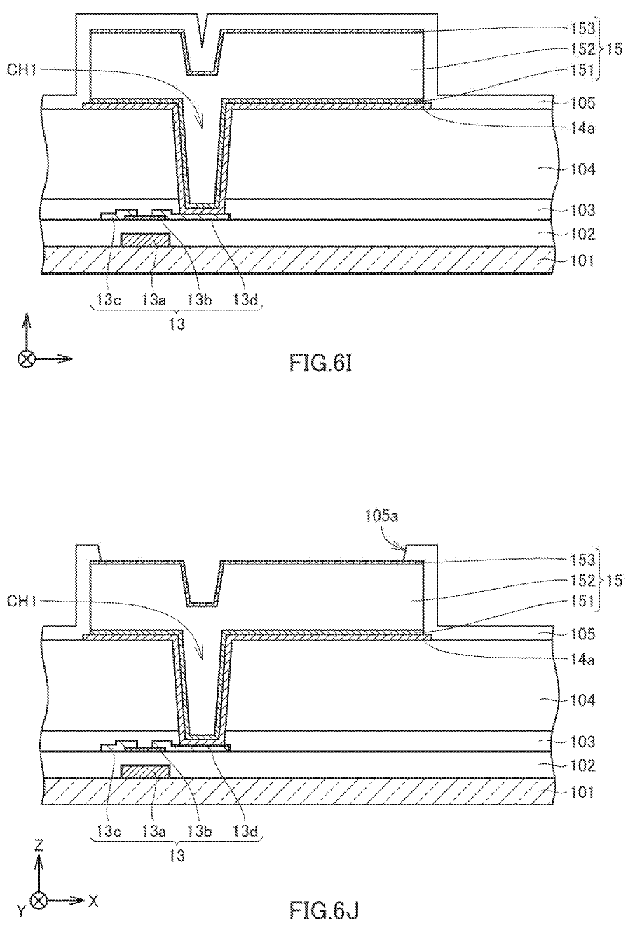

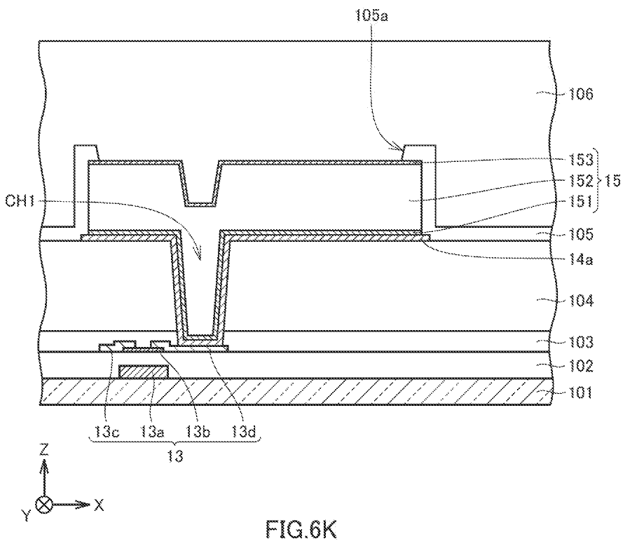

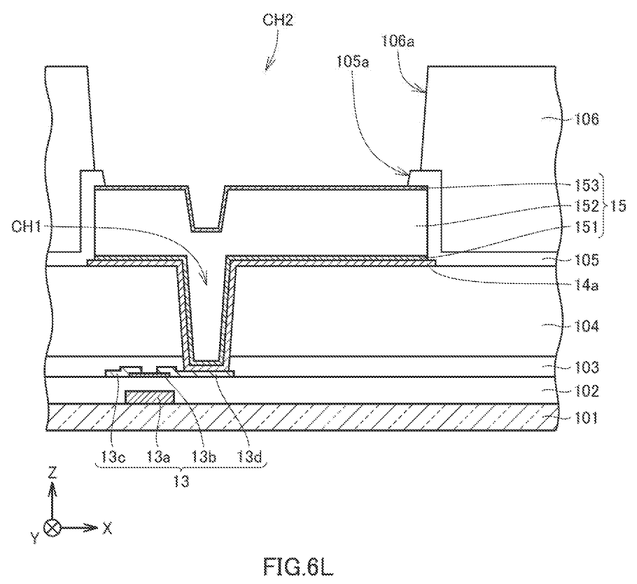

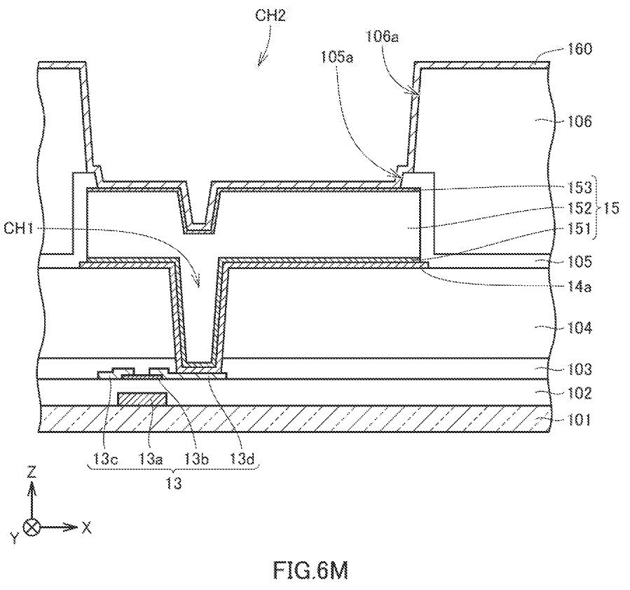

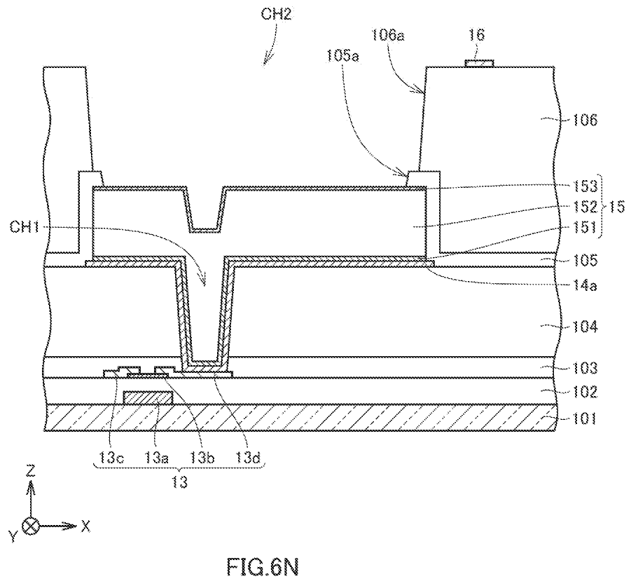

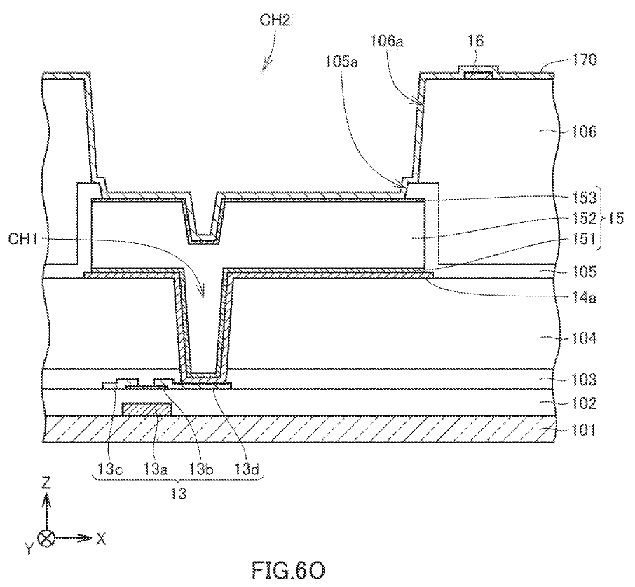

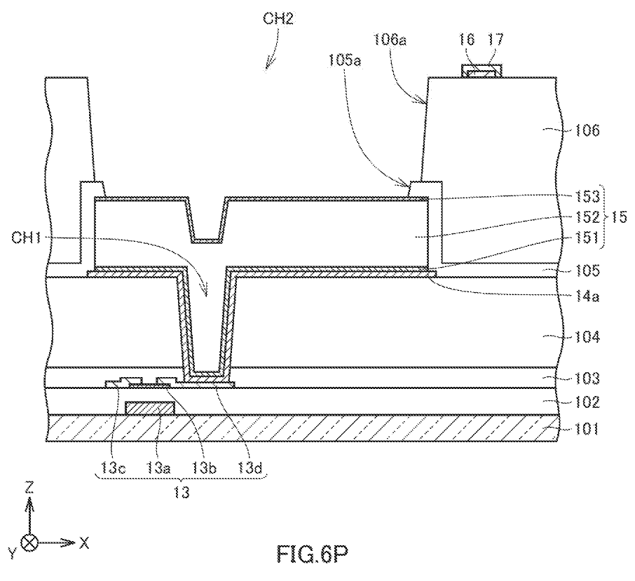

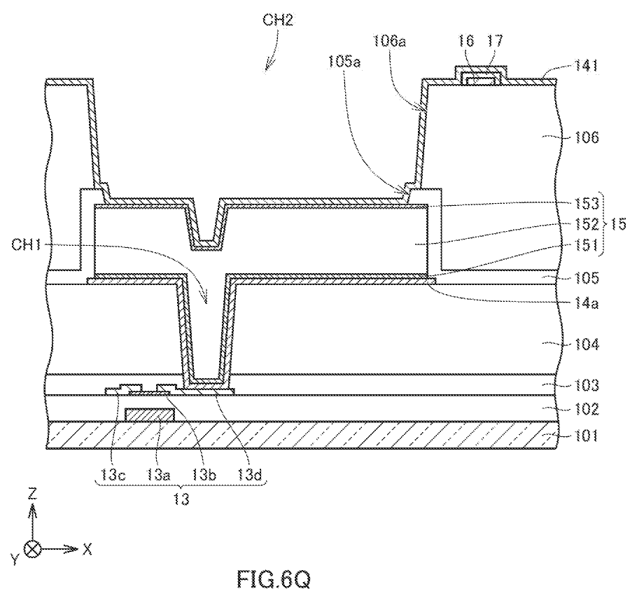

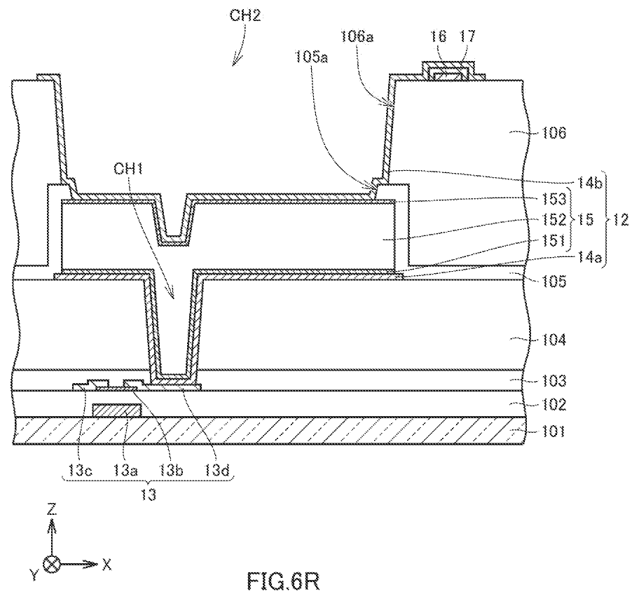

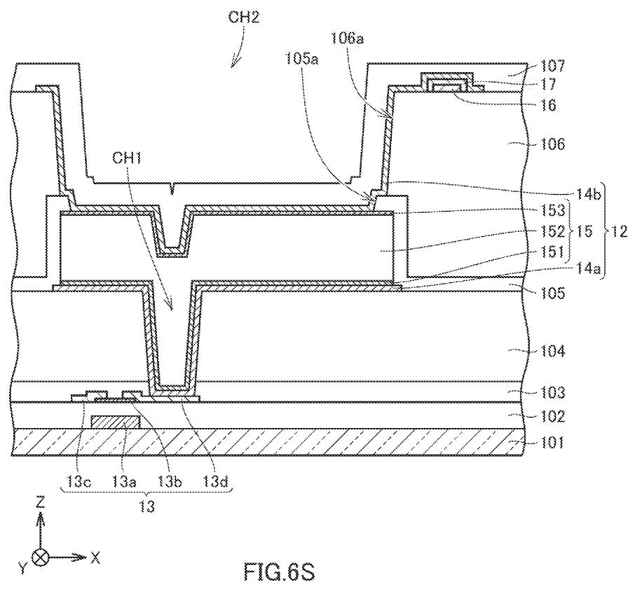

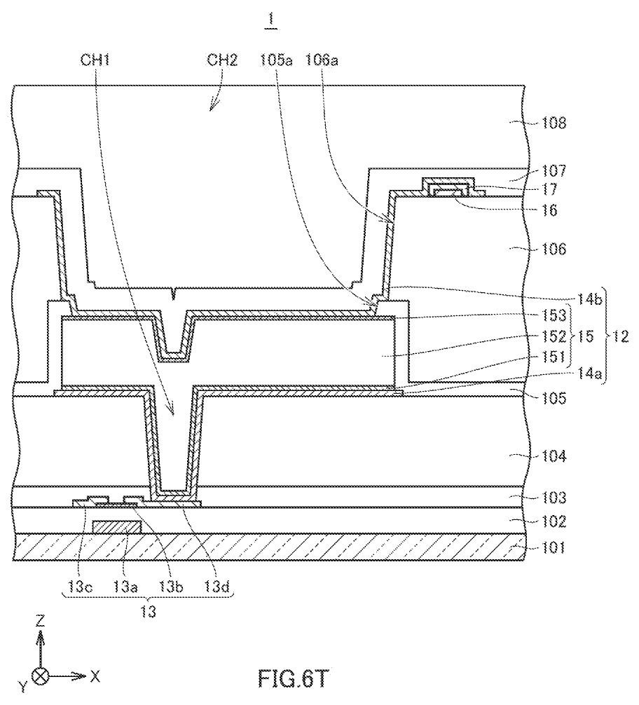

Next, the following description describes a method for producing the active matrix substrate 1. FIGS. 6A to 6T are cross-sectional views (taken along line A-A in FIG. 3) in respective steps of the method for producing the active matrix substrate 1.

As shown in FIG. 6A, the gate insulating film 102 and the TFT 13 are formed on the substrate 101 by using a known method, and the first insulating film 103 made of silicon nitride (SiN) is formed so as to cover the TFT 13 by using, for example, plasma CVD.

Subsequently, a heat treatment at about 350° C. is applied to an entire surface of the substrate 101, photolithography and wet etching are carried out so as to pattern the first insulating film 103, whereby the opening 103a is formed on the drain electrode 13d (see FIG. 6B).

Next, the second insulating film 104 made of acrylic resin or siloxane-based resin is formed on the first insulating film 103 by using, for example, slit-coating (see FIG. 6C).

Then, the opening 104a in the second insulating film 104 is formed on the opening 103a by using photolithography. Through these steps, the contact hole CH1 composed of the openings 103a and 104a is formed (see FIG. 6D).

Subsequently, the metal film 140 made of molybdenum-niobium (MoNb) is formed on the second insulating film 104 by using, for example, sputtering (see FIG. 6E).

Then, photolithography and wet etching are carried out so as to pattern the metal film 140. As a result, the lower electrode 14a connected through the contact hole CH1 with the drain electrode 13d is formed on the second insulating film 104 (see FIG. 6F).

Next, the n-type amorphous semiconductor layer 151, the intrinsic amorphous semiconductor layer 152, and the p-type amorphous semiconductor layer 153 are formed in this order so as to cover the second insulating film 104 and the lower electrode 14a by using, for example, plasma CVD (see FIG. 6G).

Then, photolithography and dry etching are carried out, whereby the n-type amorphous semiconductor layer 151, the intrinsic amorphous semiconductor layer 152, and the p-type amorphous semiconductor layer 153 are patterned. As a result, the photoelectric conversion layer 15 is formed (see FIG. 6H).

Next, the third insulating film 105 made of silicon nitride (SiN) is formed so as to cover the surface of the photoelectric conversion layer 15, by using, for example, plasma CVD (see FIG. 6I).

Then, photolithography and wet etching are carried out so as to pattern the third insulating film 105, whereby the opening 105a of the third insulating film 105 is formed on the photoelectric conversion layer 15 (see FIG. 6J). For this wet etching, for example, an etchant containing hydrofluoric acid may be used.

Subsequently, the fourth insulating film 106 made of acrylic resin or siloxane-based resin is formed on the third insulating film 105 by using, for example, slit-coating (see FIG. 6K). Thereafter, photolithography and wet etching are carried out, whereby the opening 106a of the fourth insulating film 106 is formed on the opening 105a of the third insulating film 105 (see FIG. 6L). The opening 106a of the fourth insulating film 106 has an opening width greater than that of the opening 105a of the third insulating film 105. Through these steps, the contact hole CH2 composed of the openings 105a and 106a is formed.

Next, the metal film 160 obtained by laminating molybdenum-niobium (MoNb), aluminum (Al), and molybdenum-niobium (MoNb) sequentially in this order is formed on the fourth insulating film 106 by using, for example, sputtering (see FIG. 6M).

Then, photolithography and wet etching are carried out so as to pattern the metal film 160. Through these steps, on an outer side with respect to the photoelectric conversion layer 15, on the fourth insulating film 106, the bias line 16 is formed (see FIG. 6N).

Thereafter, a metal film 170 made of molybdenum-niobium (MoNb) is formed by using, for example, sputtering, so as to cover the bias line 16 (see FIG. 6O). Then, photolithography and wet etching are carried out so as to pattern the metal film 170. Through these steps, the protection film 17 covering the surface of the bias line 16 is formed (see FIG. 6P).

Next, a native oxide adhering to a surface of the photoelectric conversion layer 15, that is, a surface of the p-type amorphous semiconductor layer 153 is removed by etching with use of hydrofluoric acid. Through these steps, the surface of the p-type amorphous semiconductor layer 153 is cleaned. Here, the protection film 17 is exposed to hydrofluoric acid. The protection film 17, however, is formed with a metal film made of molybdenum-niobium (MoNb), and it is unlikely that the film would be dissolved by etching with use of hydrofluoric acid. The protection film 17 therefore is not affected by the etching with use of hydrofluoric acid, and hence, the bias line 16 covered with the protection film 17 is not affected by the etching with use of hydrofluoric acid, either. The width of the bias line 16 is kept fixed, and the bias line 16 is prevented from having a higher resistance. Here, the surface of the p-type amorphous semiconductor layer 153 is cleaned with use of hydrofluoric acid, but the cleaning may be carried out with use of ammonium fluoride solution.

Subsequently, a transparent conductive film 141 made of ITO is formed by using, for example, sputtering so as to cover the p-type amorphous semiconductor layer 153, the protection film 17, and the fourth insulating film 106 (see FIG. 6Q). Then, photolithography and dry etching are carried out so as to pattern the transparent conductive film 141. Through these steps, the upper electrode 14b in contact with the p-type amorphous semiconductor layer of the photoelectric conversion layer 15 and the protective film 17 is formed (see FIG. 6R).

Thereafter, the fifth insulating film 107 made of silicon nitride (SiN) is formed by using, for example, plasma CVD, so as to cover the upper electrode 14b and the protection film 17 (see FIG. 6S).

Subsequently, the sixth insulating film 108 made of acrylic resin or siloxane-based resin is formed on the fifth insulating film 107 by using, for example, slit-coating, (see FIG. 6T).

What is described above is a method for producing the active matrix substrate 1 in the present embodiment. As described above, in the present embodiment, the surface of the p-type amorphous semiconductor layer 153 is cleaned by using hydrofluoric acid before the upper electrode 14b is formed. Here, since the surface of the bias line 16 is covered with the protection film 17, aluminum (Al) contained in the bias line 16 is not dissolved by the cleaning treatment with use of hydrofluoric acid, resulting in that the width of the bias line 16 is kept fixed. As a result, the resistance of the bias line 16 does not increase, and it is unlikely that X-ray detection defects would occur.

### (Operation of X-Ray Imaging Device 100)

Here, operations of the X-ray imaging device 100 illustrated in FIG. 1 are described. First, X-rays are emitted from the X-ray source 3. Here, the control unit 2 applies a predetermined voltage (bias voltage) to the bias line 16 (see FIG. 3 and the like). X-rays emitted from the X-ray source 3 are transmitted through an object S, and are incident on the scintillator 4. The X-rays incident on the scintillator 4 are converted into fluorescence (scintillation light), and the scintillation light is incident on the active matrix substrate 1. When the scintillation light is incident on the photodiode 12 provided in each pixel in the active matrix substrate 1, the scintillation light is changed to charges by the photodiode 12 in accordance with the amount of the scintillation light. A signal according to the charges obtained by conversion by the photodiode 12 is read out through the source line 10 to the signal reading unit 2B (see FIG. 2 and the like) when the TFT 13 (see FIG. 3 and the like) is in the ON state according to a gate voltage (positive voltage) that is output from the gate control unit 2A through the gate line 11. Then, an X-ray image in accordance with the signal thus read out is generated in the control unit 2.

### Embodiment 2

As the present embodiment, a method for producing the active matrix substrate 1 of Embodiment 1, which is different from the method of Embodiment 1, is described. The following description describes steps different from those in Embodiment 1.

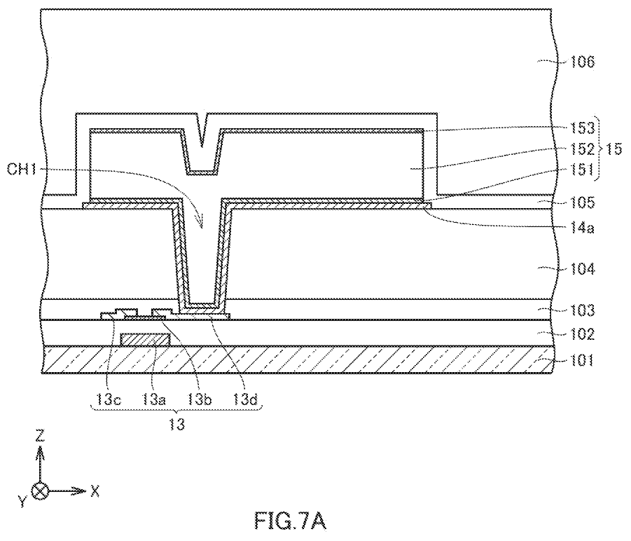

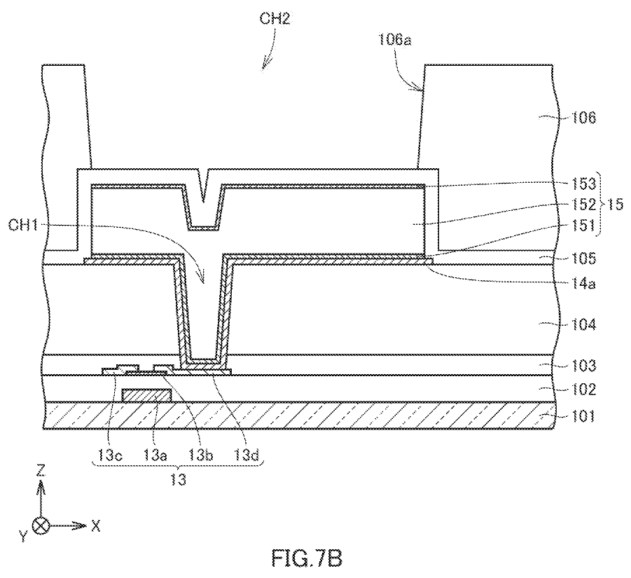

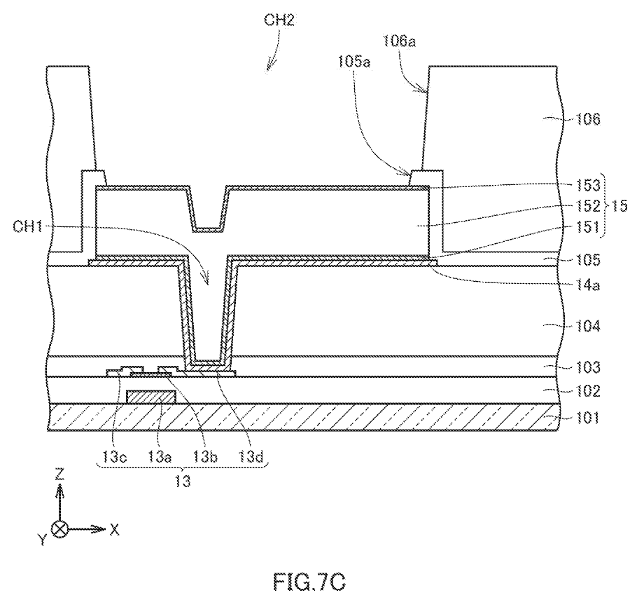

After the steps shown in FIGS. 6A to 6I, the opening 105a of the third insulating film 105 is formed in Embodiment 1; in the present embodiment, however, the step shown in FIG. 6I is subsequently followed by a step of forming the fourth insulating film 106 by using, for example, slit coating (see FIG. 7A).

Thereafter, photolithography and wet etching are carried out so that the opening 106a of the fourth insulating film 106 is formed on the photoelectric conversion layer 15 (see FIG. 7B).

Subsequently, photolithography and wet etching are carried out so that the opening 105a of the third insulating film 105 is formed on an inner side with respect to the opening 106a of the fourth insulating film 106. Here, for wet etching, hydrofluoric acid may be used as an etchant. Through these steps, the contact hole CH2 composed of the openings 105a and 106a is formed (see FIG. 7C).

Thereafter, the same steps as the above-described steps shown in FIGS. 6M to 6T are carried out, whereby the active matrix substrate 1 (see FIG. 4 and the like) is produced.

In Embodiment 2, depending on the leaving time after the opening 105a of the third insulating film 105 is formed, a native oxide is possibly formed on the surface of the p-type amorphous semiconductor layer 153. To solve this problem, the surface of the p-type amorphous semiconductor layer 153 is cleaned with use of hydrofluoric acid immediately before the upper electrode 14b is formed, whereby the contact resistance of the upper electrode 14b and the p-type amorphous semiconductor layer 153 is stabilized.

Incidentally, by using the fourth insulating film 106 as a mask, the opening of the third insulating film 105 may be formed. In this case, the end of the third insulating film 105 is recessed toward an inner side of the fourth insulating film 106, whereby the fourth insulating film 106 has a shape of jutting out with respect to the third insulating film 105. As a result, the upper electrode 14b, which is formed thereafter, tends to have disconnection at a step part between the third insulating film 105 and the fourth insulating film 106. To prevent the upper electrode 14b from having disconnection, an oxygen ashing treatment is carried out after the third insulating film 105 is etched, so that the end of the fourth insulating film 106 should be positioned on an outer side with respect to the end of the third insulating film 106. In other words, the end of the third insulating film 105 and the end of the fourth insulating film 106 are normally tapered. Here, the surface of the p-type amorphous semiconductor layer 153 is cleaned with use of hydrofluoric acid, since a native oxide adheres thereto due to an oxidation reaction.

### Embodiment 3

As the present embodiment, a method for producing the active matrix substrate 1 of Embodiment 1, which is different from the method of Embodiment 2, is described. The following description describes steps different from those in Embodiment 2.

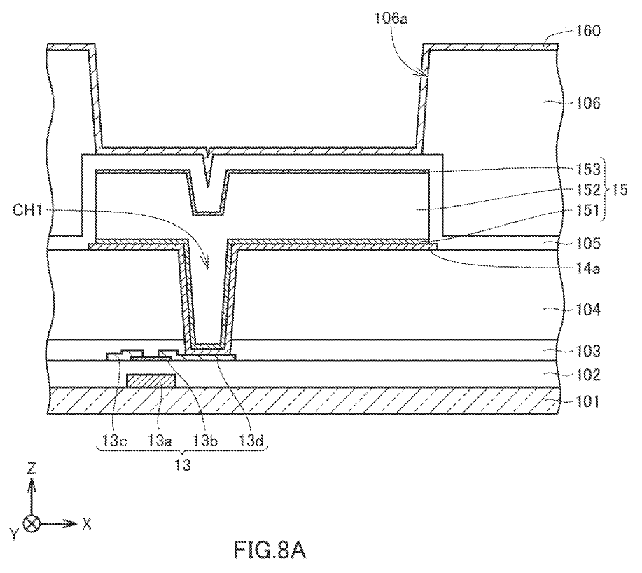

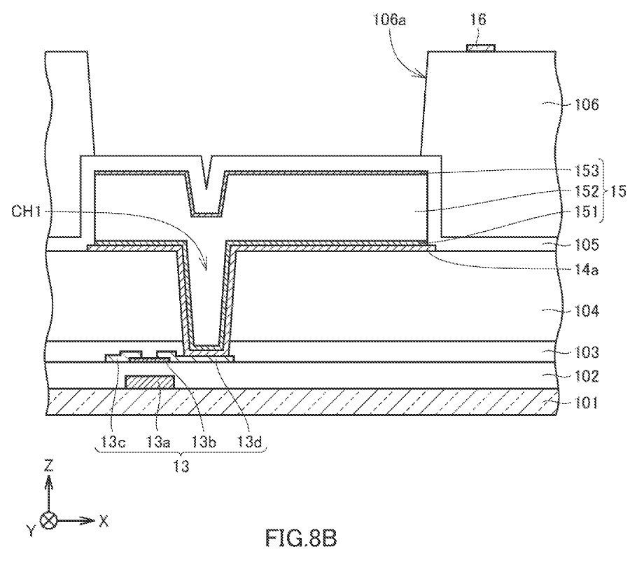

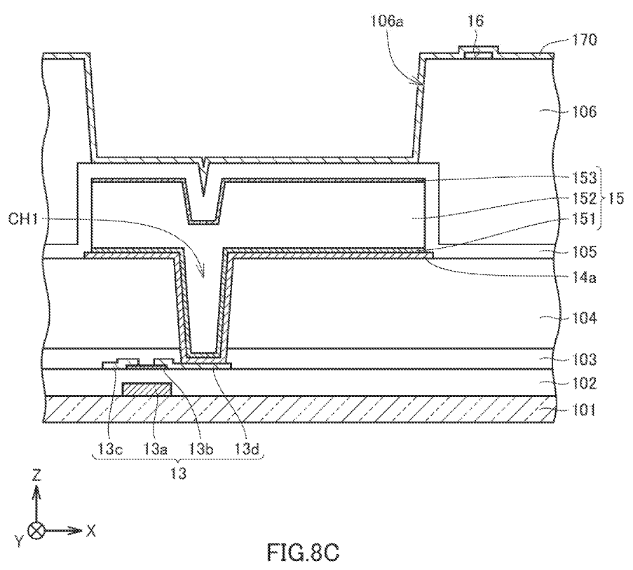

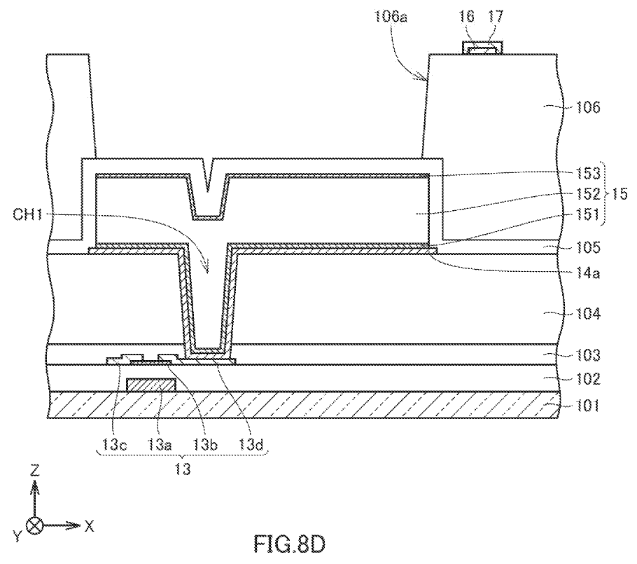

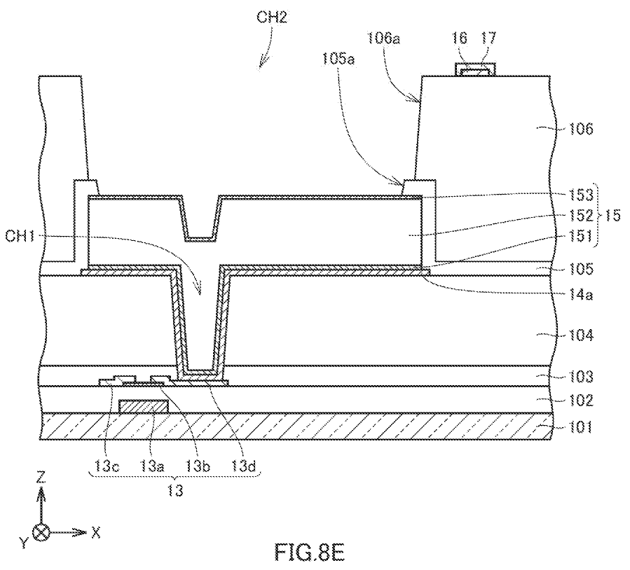

In Embodiment 2 described above, the opening 105a of the third insulating film 105 is formed after the step shown in FIG. 7B; in the present embodiment, however, after the step shown in FIG. 7B, the metal film 160 obtained by laminating molybdenum-niobium (MoNb), aluminum (Al), and molybdenum-niobium (MoNb) sequentially in this order by using, for example, sputtering is formed on the third insulating film 105 and the fourth insulating film 106 (see FIG. 8A).

Subsequently, photolithography and wet etching are carried out so as to pattern the metal film 160. Through these steps, the bias line 16 is formed on an outer side with respect to the photoelectric conversion layer 15, on the fourth insulating film 106 (see FIG. 8B).

Thereafter, the metal film 170 made of molybdenum-niobium (MoNb) is formed on the third insulating film 105 and the fourth insulating film 106 by using, for example, sputtering so as to cover the bias line 16 (see FIG. 8C).

Then, photolithography and wet etching are carried out so as to pattern the metal film 170. Through these steps, the protection film 17 covering the surface of the bias line 16 is formed (see FIG. 8D).

Next, photolithography and wet etching are carried out so that the opening 105a of the third insulating film 105 is formed on an inner side with respect to the opening 106a of the fourth insulating film 106. Here, for wet etching, hydrofluoric acid may be used as an etchant. Through these steps, the contact hole CH2 composed of the openings 105a and 106a is formed (see FIG. 8E). When the third insulating film 105 is etched, the bias line 16 is not exposed to hydrofluoric acid, since the bias line 16 is covered with the protection film 17. Further, since the protection film 17 is made of a metal material having resistance against hydrofluoric acid, the protection film 17 is not dissolved by hydrofluoric acid, and the width of the bias line 16 is kept fixed.

Thereafter, the surface of the p-type amorphous semiconductor layer 153 is cleaned with use of hydrofluoric acid, so that a natural oxide film adhering to the surface of the p-type amorphous semiconductor layer 153 is removed. Here, since the surface of the bias line 16 is covered with the protection film 17, the bias line 16 is not etched by the cleaning treatment with use of hydrofluoric acid, thereby keeping the fixed width. Then, by carrying out the same steps as the above-described steps shown in FIGS. 6Q to 6T, the active matrix substrate 1 (see FIG. 4 and the like) is produced.

In Embodiment 3, in the steps of forming the bias line 16 (see FIGS. 8A, 8B), the surface of the p-type amorphous semiconductor layer 153 is covered with the third insulating film 105. Accordingly, an oxidation reaction does not occur to the surface of the p-type amorphous semiconductor layer 153 when the bias line 16 is formed, which results in that the native oxide on the surface of the p-type amorphous semiconductor layer 153 has a smaller thickness than that in a case where an oxidation reaction occurs to the surface of the p-type amorphous semiconductor layer 153, and the thickness of the p-type amorphous semiconductor layer 153 also has a smaller decrease due to the treatment with use of hydrofluoric acid. As a result, decreasing of the thickness of the p-type amorphous semiconductor layer 153 is small, which makes it easy to form the p-type amorphous semiconductor layer 153 so that it has a desired thickness, thereby making it possible to achieve ideal diode properties more surely.

### Embodiment 4

As the present embodiment, a method for producing the active matrix substrate 1 of Embodiment 1, which is different from the methods of Embodiments 2 and 3, is described. The following description describes steps different from those in Embodiments 2 and 3.

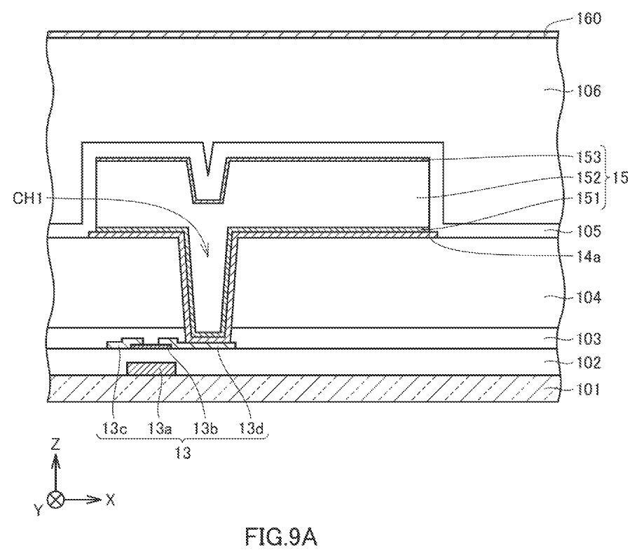

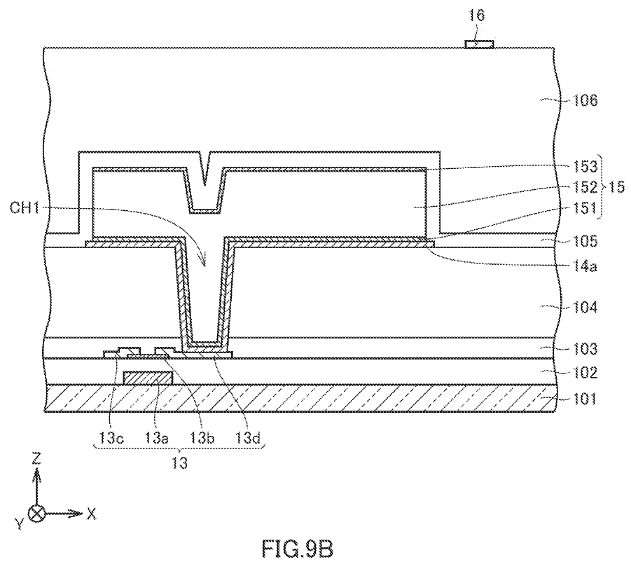

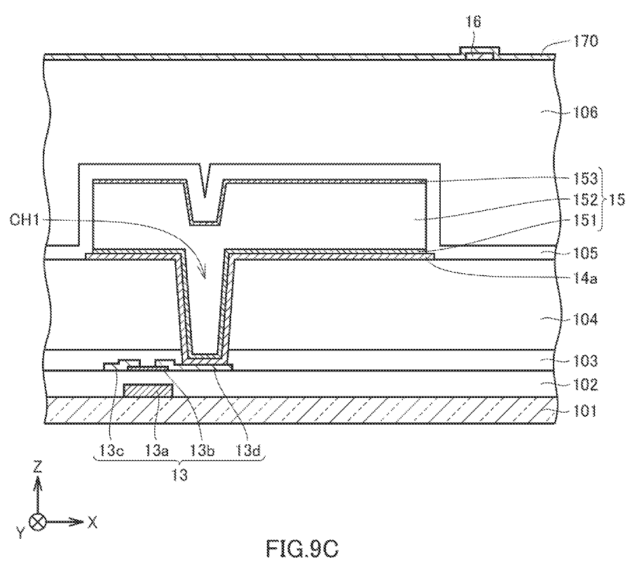

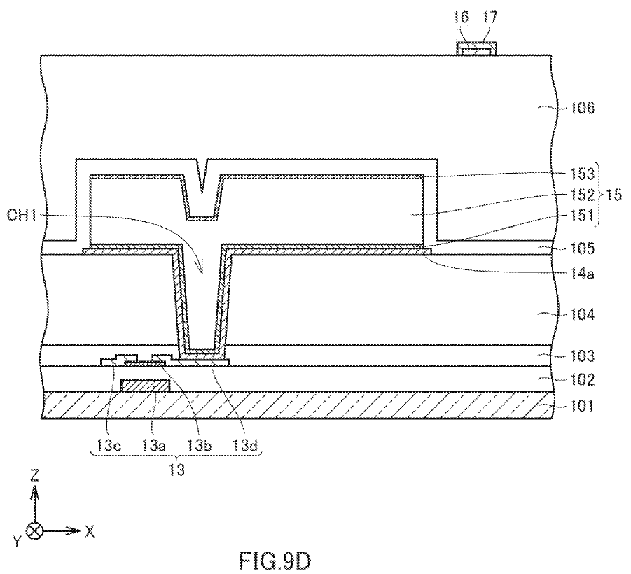

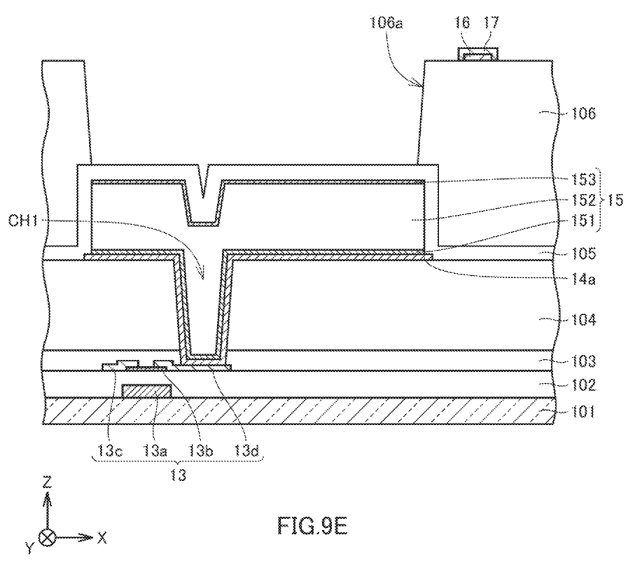

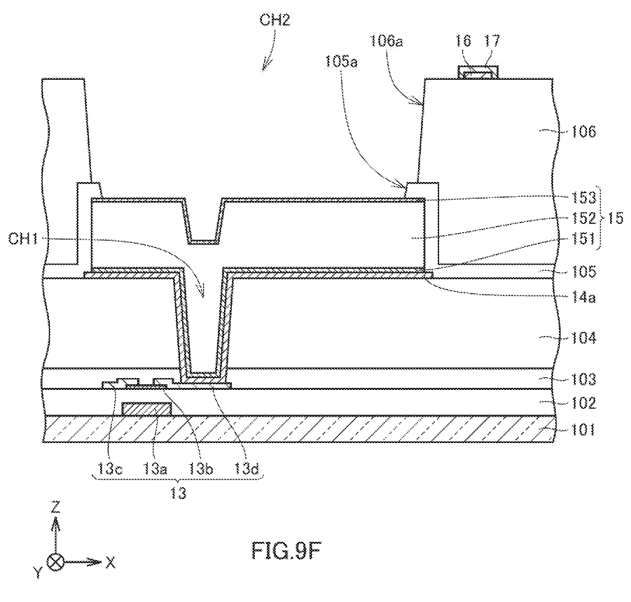

In Embodiments 2 and 3 described above, after the step shown in FIG. 7A, the opening 106a of the fourth insulating film 106 is formed; in the present embodiment, however, after the step of FIG. 7A, the metal film 160 is formed on the fourth insulating film 106 by laminating molybdenum-niobium (MoNb), aluminum (Al), and molybdenum-niobium (MoNb) sequentially in this order by, for example, sputtering (see FIG. 9A).

Subsequently, photolithography and wet etching are carried out so as to pattern the metal film 160. Through these steps, the bias line 16 is formed on an outer side with respect to the photoelectric conversion layer 15, on the fourth insulating film 106 (see FIG. 9B).

Next, the metal film 170 made of molybdenum-niobium (MoNb) is formed on the fourth insulating film 106 by, for example, sputtering so as to cover the bias line 16 (see FIG. 9C).

Then, photolithography and wet etching are carried out so as to pattern the metal film 170. Through these steps, the protection film 17 covering the surface of the bias line 16 is formed (see FIG. 9D).

Thereafter, photolithography and wet etching are carried out so that the opening 106a of the fourth insulating film 106 is formed on an inner side with respect to the photoelectric conversion layer 15 (see FIG. 9E).

Subsequently, photolithography and wet etching are carried out so that the opening 105a of the third insulating film 105 is formed on an inner side with respect to the opening 106a of the fourth insulating film 106. Here, for wet etching, hydrofluoric acid may be used as an etchant. Through these steps, the contact hole CH2 composed of the openings 105a and 106a is formed (see FIG. 9F). When the third insulating film 105 is etched, the bias line 16 is not exposed to hydrofluoric acid, since the bias line 16 is covered with the protection film 17. Further, since the protection film 17 is made of a metal material having resistance against hydrofluoric acid, the protection film 17 is not dissolved by hydrofluoric acid, and the width of the bias line 16 is kept fixed.

Thereafter, the surface of the p-type amorphous semiconductor layer 153 is cleaned with use of hydrofluoric acid, so that a native oxide adhering to the surface of the p-type amorphous semiconductor layer 153 is removed. Here, since the surface of the bias line 16 is covered with the protection film 17, the bias line 16 is not etched by the cleaning treatment with use of hydrofluoric acid, thereby keeping the fixed width. Then, by carrying out the same steps as the above-described steps shown in FIGS. 6Q to 6T, the active matrix substrate 1 (see FIG. 4 and the like) is produced.

In Embodiment 4, as is the case with Embodiment 3 described above, in the steps of forming the bias line 16, the surface of the p-type amorphous semiconductor layer 153 is covered with the third insulating film 105. Accordingly, an oxidation reaction does not occur to the surface of the p-type amorphous semiconductor layer 153 when the bias line 16 is formed, which results in that the native oxide on the surface of the p-type amorphous semiconductor layer 153 has a smaller thickness than that in a case where an oxidation reaction occurs to the surface of the p-type amorphous semiconductor layer 153, and the thickness of the p-type amorphous semiconductor layer 153 has a smaller decrease due to the treatment with use of hydrofluoric acid. As a result, fluctuations in the thickness of the p-type amorphous semiconductor layer 153 decrease, which makes it easy to form the p-type amorphous semiconductor layer 153 so that it has a desired thickness, thereby making it possible to achieve ideal diode properties more surely.

Embodiments of the present invention are described above, but the above-described embodiments are merely examples for implementing the present invention. The present invention, therefore, is not limited to the above-described embodiments, and the above-described embodiments can be appropriately varied and implemented without departing from the spirit and scope of the invention. The following description describes modification examples.

(1) In the producing methods of Embodiments 1 to 4, the step of cleaning the surface of the p-type amorphous semiconductor layer 153 with use of hydrofluoric acid is carried out before the upper electrode 14b is formed; this step, however, may be omitted.

(2) As Embodiments 1 to 4, a configuration in which the side surface of the photoelectric conversion layer 15 is covered with the third insulating film 105 and the fourth insulating film 106 (see FIG. 4 and the like) is described; the configuration, however, may be such that the fourth insulating film 106 is not provided, and the bias line 16 and the protection film 17 are provided on an outer side with respect to the photoelectric conversion layer 15, on the third insulating film 105.

### CROSS REFERENCE TO RELATED APPLICATION

The present application claims priority under 35 U.S.C. § 119 to Japanese Patent Application No. 2018-026463, filed Feb. 16, 2018. The contents of this application are incorporated herein by reference in their entirety.

1. An active matrix substrate having a plurality of detection circuitry arranged in matrix,
each of the detection circuitry comprising:
a photoelectric conversion layer;
a pair of a first electrode and a second electrode between which the photoelectric conversion layer is interposed;
an insulating film that covers a side surface of the photoelectric conversion layer;
a bias line that is provided on the insulating film and applies a bias voltage to the second electrode; and
a protection film that is provided on the insulating film, covers a surface of the bias line, and contains a conductive material having resistance against an acid,
wherein at least a part of the second electrode covers the protection film.

2. The active matrix substrate according to claim 1,
wherein the bias line is made of a metal material containing any one of aluminum, copper, and silver.

3. The active matrix substrate according to claim 1,
wherein the insulating film has an opening on the photoelectric conversion layer, and
the second electrode is in contact with the photoelectric conversion layer in the opening.

4. The active matrix substrate according to claim 1,
wherein the acid contains hydrofluoric acid.

5. An X-ray imaging panel comprising:
the active matrix substrate according to claim 1; and
a scintillator that convers irradiated X-rays into scintillation light.

6. A method for producing an active matrix substrate that has a plurality of detection circuitry arranged in matrix, the producing method comprising the steps of, in each of areas where the detection circuitry on the substrate are provided, respectively:
forming a first electrode;
forming a photoelectric conversion layer on the first electrode;
forming an insulating film that has an opening on the photoelectric conversion layer and covers a side surface of the photoelectric conversion layer;
forming a bias line on an outer side with respect to the photoelectric conversion layer, on the insulating film;
forming a protection film covering a surface of the bias line, on the insulating film; and
forming a second electrode that is in contact with the photoelectric conversion layer in the opening, and the overlaps the with the protection film,
wherein the protection film contains a conductive material having resistance against acid.

7. The producing method according to claim 6,
wherein the acid contains hydrofluoric acid.

8. The producing method according to claim 6, further comprising the step of:
cleaning a surface of the photoelectric conversion layer with hydrofluoric acid, the cleaning step being carried out after the step of forming the protection film, and before the step of forming the second electrode.

9. The producing method according to claim 6,
wherein, in the step of forming the insulating film, the insulating film is formed so as to cover the photoelectric conversion layer, and after the steps of forming the bias line and forming the protection film are carried out, the insulating film on the photoelectric conversion layer is etched with use of hydrofluoric acid so that the opening is formed at a position overlapping the photoelectric conversion layer in a planar view.
